(19) United States
(12) Patent Application Publication
(10) Pub. No.: US 2013/0208424 A1
(43) Pub. Date: Aug. 15, 2013

(54) SOLID VIA PINS FOR IMPROVED THERMAL AND ELECTRICAL CONDUCTIVITY

(71) Applicants: Robert W. Warren, Newport Beach, CA (US); Nic Rossi, Causeway Bay (HK)

(72) Inventors: Robert W. Warren, Newport Beach, CA (US); Nic Rossi, Causeway Bay (HK)

(21) Appl. No.: 13/767,759

(22) Filed: Feb. 14, 2013

Related U.S. Application Data
(60) Provisional application No. 61/598,765, filed on Feb. 14, 2012.

(51) Int. Cl. H05K 7/20; H05K 3/00

(52) U.S. Cl. CPC H05K 7/205; H05K 3/0094
USPC 361/712; 29/852

(57) ABSTRACT

A circuit comprising an integrated circuit disposed on a substrate. A via disposed adjacent to the integrated circuit. A solid metallic pin disposed within the via and configured to conduct heat generated by the integrated circuit to a heat sink.

### RELATED APPLICATIONS

This application claims benefit of U.S. Provisional Patent Application 61/598,765, entitled “Solid Via Pins for Electrical and Thermal Conductivity in Package Substrates or PCBS,” filed Feb. 14, 2012, which is hereby incorporated by reference for all purposes.

### TECHNICAL FIELD

The present disclosure relates to semiconductor circuits, and more specifically to solid via pins for improved thermal and electrical conductivity, such as for use in package substrates or printed circuit boards.

### BACKGROUND OF THE INVENTION

Heat generated within a semiconductor package can cause damage to electronic components of the semiconductor package. Structures for managing heat dissipation of heat generated within a semiconductor package include adding heat spreaders to the semiconductor package and using high thermal conductivity mold compounds on or within the semiconductor package.

### SUMMARY OF THE INVENTION

A circuit comprising an integrated circuit disposed on a substrate is provided that includes a via disposed adjacent to the integrated circuit, such as in a heat conducting structure. A solid metallic pin is disposed within the via and is configured to conduct heat generated by the integrated circuit to a heat sink.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

### BRIEF DESCRIPTION OF THE SEVERAL VIEWS OF THE DRAWINGS

Aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views, and in which:

FIG. 1 is a diagram of a copper-plated PTH via in accordance with an exemplary embodiment of the present disclosure;

FIG. 2 is a diagram of an interference or press fit via pin configuration in accordance with an exemplary embodiment of the present disclosure; and

FIG. 3 is a diagram of a swage mount via pin configuration in accordance with an exemplary embodiment of the present disclosure.

### DETAILED DESCRIPTION OF THE INVENTION

In the description that follows, like parts are marked throughout the specification and drawings with the same reference numerals. The drawing figures might not be to scale and certain components can be shown in generalized or schematic form and identified by commercial designations in the interest of clarity and conciseness.

Adequate heat dissipation is essential in semiconductor packages. As semiconductor dies within the packages continue to utilize smaller node geometries, heat density within the semiconductor dies continues to increase. If the temperature of critical areas of semiconductor dies exceeds specified junction temperatures, thermal damage or a reduction in operating life can result. In addition, the package size, complexity and costs can increase significantly when high levels of heat dissipation are required.

Because high performance packages continue to require higher operating speeds with lower voltage drops, power loss and noise, semiconductor substrate interconnect inductance, resistance and capacitance must also be optimized to ensure optimal performance.

Standard plated through-hole (PTH) vias are a major limiting factor for achieving high thermal and electrical performance in semiconductor substrates, primarily due to the low amount of plated copper in the vias that is available to conduct and dissipate heat. Standard PTH vias typically receive a thin copper plating on the interior sidewalls of the vias having a thickness in the range of 10-15 μm. Standard PTH vias can optionally be filled with a thermal epoxy matrix containing silver, for example. However, thermal epoxy matrixes have substantially lower electrical and thermal conduction qualities compared to pure silver or copper plating. In addition, where solder is applied to a standard PTH via, a solder mask can typically be used on the bottom of the open via to prevent undesired solder flow. However, the effectiveness of such solder masks alone is limited. If a standard PTH via is too wide, the solder mask may open up during soldering. If the bottom of the via is not covered, solder may flow through the via and wick out onto the bottom of the PCB or semiconductor substrate, causing an undesirable reduction in thermal conductivity as well as potential unintended electrical contact with other portions of the semiconductor package.

Previous attempts to address heat dissipation problems from the semiconductor substrate to the PCB have included: adding heat spreaders within the semiconductor package, using higher thermal conductivity mold compounds, increasing the semiconductor package layer count or semiconductor package size, using higher thermal conductivity die attach epoxies, using thicker copper plating in the PTH vias, using larger diameter PTH vias, or filling PTH vias with thermally conductive epoxy. However, such methods may undesirably decrease design density, and the incremental improvement in thermal dissipation each of these methods provides may be very costly. Moreover, completely filling the PTH vias with copper may be impractical due to very high fabrication costs and poor manufacturability due to uncontrollable voiding within the PTH vias. Similar attempts have been made to address undesirably high interconnect inductance, resistance and capacitance. However, the improvements in electrical performance from the above methods are likewise incremental and very costly.

The present application sets forth a method and system for improving electrical and thermal conductivity in package substrates or printed circuit boards (PCBs), for example. The novel concept utilizes solid copper alloy pins, inserted into pre-drilled and copper-plated PTH vias, to increase thermal conductivity and/or improve electrical connectivity from a semiconductor substrate or die to an underlying PCB, for example. The pins can be similar to pins used in PCB assembly for connectors, but can be much smaller in length and diameter to accommodate the higher design density requirements of semiconductor substrates. Standard surface mount pick and place equipment can be utilized to insert the pins, which can be gang mounted into the PTH vias to reduce assembly cycle time and costs. Each of the pins can be locked into place in the PTH vias by swaging, i.e., cold welding or riveting. Alternatively, each of the pins can be locked into place by press-fitting, utilizing pins having design aspects and tolerances which allow sufficient physical contact between a pin and the copper-plated PTH sidewall.

Such PTH vias and pins can be selectively placed in areas of a semiconductor substrate, for example, requiring high thermal dissipation capacity and/or electrical conductivity. In one exemplary implementation, a semiconductor die can be attached to a semiconductor substrate using a silver-filled epoxy. In this exemplary embodiment, an array of pins can be inserted into an array of PTH vias within the semiconductor substrate and under the semiconductor die. Thus, thermal dissipation can occur not only through the copper plating on the sidewalls of each of the PTH vias, but also through each of the pins within the PTH vias.

In another exemplary embodiment, an array of pins can be inserted into an array of PTH vias within a PCB. A semiconductor device or die can then be soldered to the pins to thermally and/or electrically connect the semiconductor device or die to the PCB. In this exemplary embodiment, the solder on top of each of the pins can wet down into the PTH vias, wicking into any spaces between the copper plating of the PTH vias and the pins. Thus, thermal dissipation can be substantially improved over standard PTH vias alone by providing a highly thermally conductive path through the pins. In addition, the PTH vias of the present application can also have a reduced inductance, capacitance, and/or resistance as compared to standard PTH vias.

The present inventive concepts provide a low cost method for creating substrate PTH vias with very low electrical inductance and high thermal conductivity, including a reduction in via thermal resistance from greater than 65 degrees Celsius per watt to less than 20 degrees Celsius per watt as compared to a standard PTH via and a reduction in via inductance from greater than 1.32 nH to approximately 0.138 nH as compared to a standard PTH via. The PTH vias of the present disclosure provide a better mechanical attachment at the top of the PTH via as compared to a standard PTH via, and can be applied to semiconductor package substrates, or PBCs, such as motherboards and application boards, or other suitable application requiring a high degree of thermal and/or electrical conductivity in limited cross sections.

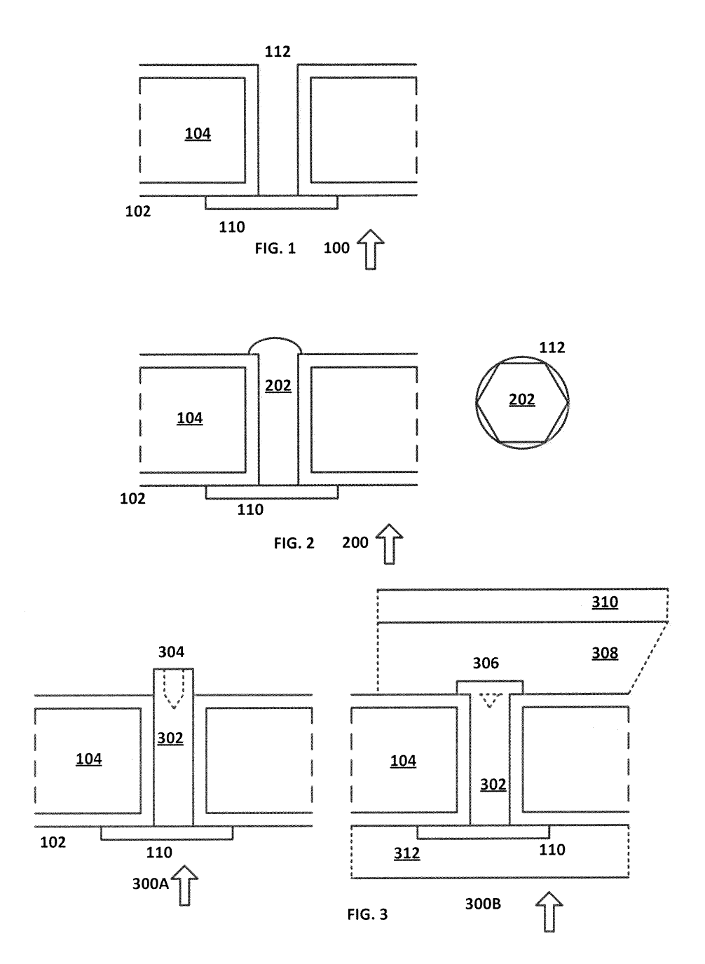

FIG. 1 is a diagram of a copper-plated PTH via 100 in accordance with an exemplary embodiment of the present disclosure. Plated via 100 includes plated surface 102, which is formed on resin layer 104. Plated surface 102 can be formed by copper plating or other suitable materials, and includes through-hole plating and a capture pad on the surface of resin layer 104 adjacent to the via, in order to improve thermal and electrical contact between the via pin and the plated surface 102. Resin layer 104 can be a Bismaleimide-Triazine (BT) resin structure, a printed circuit board or other suitable materials. Plated surface 102 is formed on a drilled or otherwise formed via hole 112, and solder mask tenting 110 is provided to facilitate the placement and securing of via pins within via hole 112. As discussed above, solid copper alloy pins can be inserted into copper-plated PTH via 100 to increase thermal conductivity and/or improve electrical connectivity from a semiconductor substrate or die to an underlying PCB or for other suitable purposes.

FIG. 2 is a diagram of an interference or press fit via pin configuration 200 in accordance with an exemplary embodiment of the present disclosure. Pin 202 can have a hexagonal shape, an octagonal shape or other suitable angular and non-circular shapes in order to improve the ability to install the pin into the via hole and to form an interference or press fit. Standard surface mount pick and place equipment can be used to insert pin 202 into via hole 112, after which pin 202 is compressed or otherwise secured into position.

FIG. 3 is a diagram of a swage mount via pin configuration 300A and 300B in accordance with an exemplary embodiment of the present disclosure. Via pin 302 includes hollow end 304, which is pressed after being placed in the via hole by using an arbor press or other suitable devices to form retaining head 306. As shown in 300B, an epoxy matrix 308 or other suitable material can be used to conduct heat from an integrated circuit formed on silicon die 310, or other suitable heat sources, through via pin 302 to substrate 312 or other suitable heat sinks. Likewise, other suitable heat transfer architectures can also or alternatively be used.

It should be emphasized that the above-described embodiments are merely examples of possible implementations. Many variations and modifications can be made to the above-described embodiments without departing from the principles of the present disclosure. All such modifications and variations are intended to be included herein within the scope of this disclosure and protected by the following claims.

What is claimed is:

1. A circuit comprising:
an integrated circuit disposed on a substrate;
a via disposed adjacent to the integrated circuit; and
a solid metallic pin disposed within the via and configured to conduct heat generated by the integrated circuit to a heat sink.

2. The circuit of claim 1 wherein the solid metallic pin further comprises a press fit seal against the via.

3. The circuit of claim 1 wherein the via further comprises a metallic through-hole plating and a metallic capture pad.

4. The circuit of claim 1 wherein the solid metallic pin has an angled cross section.

5. The circuit of claim 1 wherein the solid metallic pin further comprises a swaged retaining head.

6. The circuit of claim 1 wherein the via is disposed in an insulating structure that is disposed adjacent to the substrate.

7. The circuit of claim 1 further comprising a heat conductor disposed between the integrated circuit and the via.

8. The circuit of claim 1 further comprising solder mask tenting disposed on one end of the via.

9. A circuit comprising:
an integrated circuit disposed on a substrate;
a via disposed in an insulating structure adjacent to the integrated circuit, the via further comprises copper plating;
a heat conductor disposed between the integrated circuit and the via;
a solid metallic pin disposed within the via and configured to conduct heat generated by the integrated circuit to a heat sink, the solid metallic pin being press fit or swaged to form a seal against the via, the solid metallic pin having a hexagonal cross section;
solder mask tenting disposed on one end of the via opposite the seal; and
a heat sink disposed adjacent to the solder mark tenting.

10. A method of fabricating a circuit comprising:
forming a via in an insulator;
forming solder mask tenting at one end of the via;
plating the via with a metallic substance;
inserting a metallic pin into the via;
sealing the metallic pin against the plating; and
disposing an integrated circuit adjacent to the via.

11. The method of claim 10 wherein forming the via in the insulator comprises drilling a hole in a printed circuit board.

12. The method of claim 10 wherein plating the via with the metallic substance comprises forming a capture pad on a surface of the insulator adjacent to the via.

13. The method of claim 10 wherein forming the via in the insulator comprises drilling a hole in a Bismaleimide-Triazine (BT) resin structure.

14. The method of claim 10 wherein inserting the metallic pin into the via comprises inserting the metallic pin into the via using standard surface mount pick and place equipment.

15. The method of claim 10 wherein sealing the metallic pin against the plating comprises press fitting the metallic pin.

16. The method of claim 10 wherein sealing the metallic pin against the plating comprises swage mounting the metallic pin.

17. The method of claim 10 wherein disposing the integrated circuit adjacent to the via comprises:
disposing a thermal conductor layer over the via; and
disposing the integrated circuit on the thermal conductor layer.

18. The method of claim 10 forming the via in the insulator comprises drilling a hole in a printed circuit board, wherein plating the via with the metallic substance comprises forming a capture pad on a surface of the insulator adjacent to the via, wherein inserting the metallic pin into the via comprises inserting the metallic pin into the via using standard surface mount pick and place equipment, wherein sealing the metallic pin against the plating comprises press fitting or swage mounting the metallic pin, and wherein disposing the integrated circuit adjacent to the via comprises:
disposing a thermal conductor layer over the via; and
disposing the integrated circuit on the thermal conductor layer.
